(19) United States
(12) Patent Application Publication
(10) Pub. No.: US 2008/0224295 A1
(43) Pub. Date: Sep. 18, 2008

(54) Package structure and stacked package module using the same

(75) Inventors: Chung-Cheng Lien, Hsinchu (TW); Chia-Wei Chang, Hsinchu (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/073,734

(22) Filed: Mar. 10, 2008

(30) Foreign Application Priority Data
Mar. 16, 2007 (TW) 096109063

(51) Int. Cl. H01L 23/498

(52) U.S. Cl. 257/686; 257/702; 257/E23.062; 257/E23.063; 257/E23.069

(57) ABSTRACT

A package structure with chip embedded therein is disclosed, which comprises a circuit board having a first surface, an opposite second surface and a through cavity penetrating the circuit board, wherein the first surface of the circuit board has a plurality of first conductive pads and a plurality of wire bonding pads disposed thereon, and the second surface of the circuit board has a plurality of second conductive pads disposed thereon; and a chip embedded in the through cavity of the circuit board, wherein the gap between the through cavity and the chip is filled with a filling material, the chip has an active surface with a plurality of electrode pads and an inactive surface, and the electrode pads electrically connect to the wire bonding pads of the circuit board by a plurality of metal lines. The present invention further provides a package module using the aforementioned package structure.

### BACKGROUND OF THE INVENTION

1. Field of the Invention

The present invention relates to a package structure and a stacked package module using the same and, more particularly, to a package structure which can reduce the conventional height of the package module and a stacked package module using the same.

2. Description of Related Art

As the electronic industry continues to boom, the design trend of electronic devices is towards multifunction and high-performance. Thus, high-density integration and miniaturization are necessary for a semiconductor package structure. On the ground of the reason aforementioned, the mono-layered circuit boards providing active components, passive components, and circuit connection, are being replaced by the multi-layered circuit boards. The area of circuit layout on the circuit board increases in a restricted space by interlayer connection to meet with the requirement of high-density integration.

In general, a conventional semiconductor package structure is made such that a semiconductor chip is mounted by its back surface on the top surface of a circuit board, then the package structure is finished through wire bonding, or a semiconductor chip is mounted by the active surface thereof on the top surface of the circuit board, thereby finishing a flip-chip package structure, followed by placing solder balls on the back surface of the circuit board to provide electrical connections for an electronic device like a printed circuit board.

FIG. 1 shows a conventional wire bond package structure. The wire bond package structure 1 comprises a circuit board 10, a chip 11, a plurality of metal lines 14, and an encapsulant 15. The circuit board 10 has a first surface 10a (for adhering a chip) having a plurality of wire bonding pads 101 and an opposite second surface 10b (for adhering solder balls) having a plurality of solder pads 102. The chip 11 is disposed on the first surface 10a of the circuit board 10, and the active surface 11a of the chip 11 has a plurality of electrode pads 111 electrically connecting to the wire bonding pads 101 of the circuit board 10 by the metal lines 14. In addition, the encapsulant 15 wraps the chip 11 and the metal lines 14. The solder pads 102 of the circuit board 10 can electrically connect with a printed circuit board by solder balls 16.

In the aforementioned wire bond package structure, the chip 11 is mounted on the first surface 10a of the circuit board 10, and electrically connects to the circuit board 10 by the metal lines 14. Thereby, the height of the package structure increases, and cannot meet with the requirement for compact size. In addition, since the chip 11 mounted on the circuit board 10 generates a large amount of heat in high-speed operation, given the large amount of heat not released efficiently into the environment, the integrated circuit in the chip 11 will not function well, resulting in temporary or permanent damage. Consequently, the poor efficiency for heat dissipating of the package structure compromises the quality of the package structure.

Accordingly, another conventional wire bond package structure with a chip embedded therein has been developed, with reference to FIG. 2. The package structure 2 comprises a circuit board 20, a chip 21, a plurality of metal lines 24, and an encapsulant 25. The circuit board 20 has a first surface 20a having a plurality of wire bonding pads 201 and an opposite second surface 20b having a plurality of solder pads 202. In addition, the circuit board 20 has a through cavity 205, and the chip 21 is disposed in the through cavity 205. The active surface 21a of the chip 21 has a plurality of electrode pads 211, electrically connecting to the wire bonding pads 201 of the circuit board 20 by the metal lines 24. The through cavity 205 of the circuit board 20 is filled with the encapsulant 25, and the encapsulant 25 wraps the chip 21 and the metal lines 24. The solder pads 202 of the circuit board 20 can electrically connect with a printed circuit board by solder balls 26.

In comparison to the wire bond package structure shown as FIG. 1, the chip in the wire bond package structure shown as FIG. 2 is embedded in the circuit board, and thereby the height of the package structure decreases 150 μm at the least. In addition, the inactive surface of the chip embedded in the circuit board is exposed, and thereby the efficiency for heat dissipating of the package structure can be enhanced.

The step for embedding and fixing the chip 21 in the circuit board 20 is described as follows. The chip 21 is fixed temporarily in the through cavity 205 of the circuit board 20 by a release film (not shown in FIG. 2); subsequently, the electrode pads 21 of the chip 2 electrically connect to the wire bonding pads 201 of the circuit board 20 by the metal lines 24 by wire bonding; then, the through cavity 205 is filled with the encapsulant 25 and the encapsulant 25 wraps the chip 21 and the metal lines 24; and finally, the release film is removed so as to obtain the wire bond package structure with a chip embedded therein.

However, the chip 21 fixed temporarily by the release film will shift due to shaking in the process for wire bonding and thereby alignment error occurs. Although the wire bond package structure with a chip embedded therein can meet with the requirements for compact size and well efficiency for heat dissipating, it cannot resolve the issues of alignment error caused by the shift of the chip, resulting in reduced yield and increased cost.

### SUMMARY OF THE INVENTION

The object of the present invention is to provide a package structure with a chip embedded therein and the stacked package module using the package structure with a chip embedded therein as a packaging unit, which can reduce the conventional height of the package module to provide a more compact-sized and space-saving product.

Another object of the present invention is to provide a package structure with a chip embedded therein that exhibits improved efficiency for heat dissipating, resulting from the exposure of the chip.

Yet another object of the present invention is to provide a package structure with a chip embedded therein for resolving the alignment error caused by the shift of the chip in the process for wire bonding.

To achieve the aforementioned objects, the present invention provides a package structure with a chip embedded therein, comprising: a circuit board having a first surface, an opposite second surface, and a through cavity penetrating the circuit board, wherein the first surface of the circuit board has a plurality of first conductive pads and a plurality of wire bonding pads disposed thereon, and the second surface of the circuit board has a plurality of second conductive pads disposed thereon; and a chip embedded in the through cavity of the circuit board, wherein the gap between the through cavity of the circuit board and the chip is filled with a filling material to fix the chip, the chip has an active surface with a plurality of electrode pads and an inactive surface, and the electrode pads electrically connect to the wire bonding pads of the circuit board by a plurality of metal lines.

In the aforementioned package structure, the circuit board can be a two-layered or multi-layered circuit board.

The aforementioned package structure can further comprise an encapsulant to wrap the active surface, the metal lines, and the wire bonding pads of the circuit board.

The present invention further provides a stacked package module, comprising: a first package structure comprising a circuit board and a first chip, wherein the circuit board has a first surface, an opposite second surface, at least one through cavity penetrating the circuit board, a plurality of first conductive pads and a plurality of wire bonding pads disposed on the first surface, and a plurality of second conductive pads disposed on the second surface; the first chip is embedded in the through cavity of the circuit board; the gap between the through cavity of the circuit board and the first chip is filled with a filling material to fix the first chip; the first chip has an active surface with a plurality of electrode pads and an inactive surface; and the electrode pads electrically connect to the wire bonding pads of the circuit board by a plurality of metal lines; and a second package structure comprising a second chip, wherein the second package structure electrically connects to the first package structure by the first conductive pads of the first package structure.

In the aforementioned stacked package module, the second package structure can be any type of package structure. Preferably, the second package structure is the same as the first package structure, flip chip package structure, wire bond package structure, and so on.

In the aforementioned stacked package module, one surface of the second package structure has a plurality of second conductive pads, and the second conductive pads electrically connect to the first conductive pads of the first package structure. In addition, the stacked package module of the present invention can further comprise a plurality of solder balls which can electrically connect the second conductive pads of the second package structure with the first conductive pads of the first package structure.

The aforementioned stacked package module can further comprise an encapsulant. The encapsulant can wrap the active surface of the first chip, the metal lines and the wire bonding pads of the circuit board.

Accordingly, the present invention can reduce the height of the package module to provide a more compact-sized and space-saving product. In addition, the efficiency for heat dissipating can be improved, resulting from the exposure of the chip. Furthermore, the present invention can resolve the alignment error caused by the shift of the chip in the process for wire bonding. The package structure with a chip embedded therein can further electrically connect to a flip chip package structure, a wire bond package structure, or another identical package structure so as to provide various products.

Other objects, advantages, and novel features of the invention will become more apparent from the following detailed description when taken in conjunction with the accompanying drawings.

### BRIEF DESCRIPTION OF THE DRAWINGS

FIG. 1 is a cross-section view of a conventional wire bond package structure;

FIG. 2 is a cross-section view of another conventional wire bond package structure;

FIG. 3 is a cross-section view of a package structure with a chip embedded therein of a preferred embodiment of the present invention;

FIG. 4 is a cross-section view of a stacked package module of a preferred embodiment of the present invention;

FIG. 5 is a cross-section view of a stacked package module of a preferred embodiment of the present invention; and

FIG. 6 is a cross-section view of a stacked package module of a preferred embodiment of the present invention.

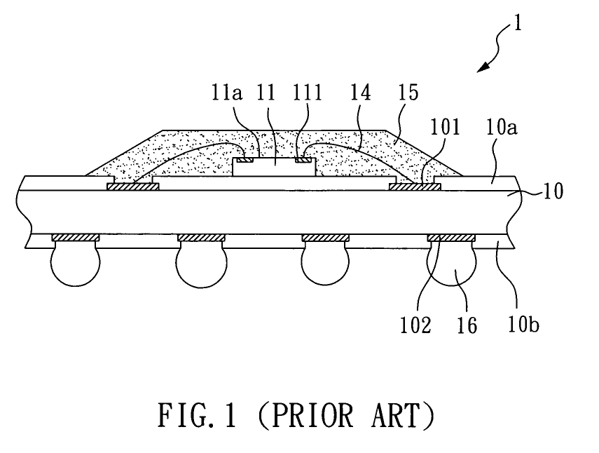

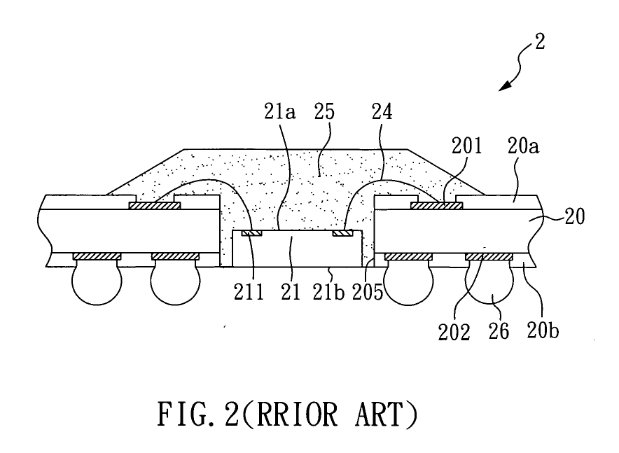

### DETAILED DESCRIPTION OF THE PREFERRED EMBODIMENT

### Embodiment 1

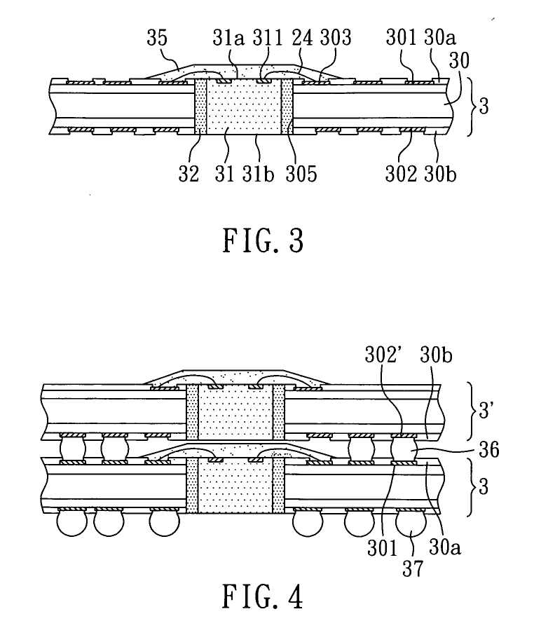

With reference to FIG. 3, there is shown a cross-section view of a package structure with a chip embedded therein. The package structure 3 with a chip embedded therein comprises a circuit board 30. The circuit board 30 has a first surface 30a, an opposite second surface 30b, and a through cavity 305 penetrating the circuit board 30. A plurality of first conductive pads 301 and a plurality of wire bonding pads 303 are disposed on the first surface 30a of the circuit board 30, and a plurality of second conductive pads 302 are disposed on the second surface 30b of the circuit board 30. The package structure 3 further comprises a chip 31 embedded in the through cavity 305 of the circuit board 30, and the gap between the through cavity 305 of the circuit board 30 and the chip 31 is filled with a filling material 32 to fix the chip 31. The chip 31 has an active surface 31a and an inactive surface 31b, and the active surface 31a of the chip 31 has a plurality of electrode pads 311. The electrode pads 311 electrically connect to the wire bonding pads 303 of the circuit board 30 by a plurality of metal lines 34, and the inactive surface 31b of the chip 31 is exposed to the second surface 30b.

Herein, the circuit board 30 of the present embodiment is a two-layered or multi-layered circuit board. The material of the filling material 32 filling the gap between the through cavity 305 of the circuit board 30 and the chip 31 to fix the chip 31 is selected from the group consisting of organic dielectric material, liquid organic resin, and prepreg. In the present embodiment, the material of the filling material 32 is prepreg. In addition, the materials of the first conductive pads 301, the wire bonding pads 303 and the second conductive pads 302 in the present embodiment are individually selected from the group consisting of copper, silver, gold, nickel/gold, nickel/palladium/gold, and the combination thereof. The material of the metal lines 34 is gold.

The package structure 3 of the present embodiment further comprises an encapsulant 35. The encapsulant 35 wraps the active surface 31a of the chip 31, the metal lines 34, and the wire bonding pads 303 of the circuit board 30. The material of the encapsulant 35 is epoxy resin.

Accordingly, the package structure can reduce the height of the package module to provide a more compact-sized and space-saving product. In addition, the efficiency for heat dissipating can be improved, resulting from the exposure of the chip. Furthermore, the chip is fixed in the through cavity of the circuit board by the filling material so as to inhibit the shift of the chip commonly resulting from shaking in the process for wire bonding and thereby reduce alignment error.

### Embodiment 2

With reference to FIG. 4, there is shown a cross-section view of a stacked package module. The stacked package module of the present embodiment is constructed by using two same package structures 3 and 3′ each with a chip embedded therein.

In detail, the second conductive pads 302′ on the second surface 30b′ of the upper package structure 3′ electrically connect to the first conductive pads 301 on the first surface 30a of the lower package structure 3 through a plurality of solder balls 36 by package on package.

### Embodiment 3

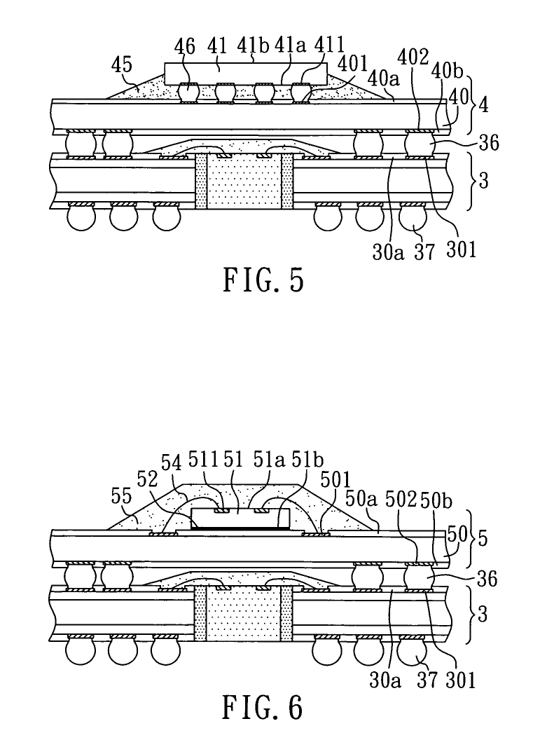

With reference to FIG. 5, there is shown a cross-section view of a stacked package module. The stacked package module of the present embodiment uses the package structure 3 of Embodiment 1 and a flip chip package structure 4 as packaging units to perform package on package. Herein, the flip chip package structure 4 comprises a substrate 40 and a chip 41. The substrate 40 has a first surface (for adhering a chip) 40a and an opposite second surface (for adhering solder balls) 40b. A plurality of first conductive pads 401 are disposed on the first surface 40a of the substrate 40, and a plurality of second conductive pads 402 are disposed on the second surface 40b of the substrate 40. The chip 41 has an active surface 41a with a plurality of electrode pads 411 thereon and an inactive surface 41b. The electrode pads 411 of the chip 41 electrically connect to the first conductive pads 401 on the first surface 40a of the substrate 40 through a plurality of solder bumps 46. In addition, the package structure 4 further comprises an underfilling material 45 formed between the chip 41 and the substrate 40. The second conductive pads 402 on the second surface 40b of the package structure 4 electrically connect to the first conductive pads 301 on the first surface 30a of the package structure 3 by a plurality of solder balls 36.

### Embodiment 4

With reference to FIG. 6, there is shown a cross-section view of a stacked package module. The stacked package module of the present embodiment uses the package structure 3 of Embodiment 1 and a wire bond package structure 5 as packaging units to perform package on package. The wire bond package structure 5 comprises a substrate 50 and a chip 51. The substrate 50 has a first surface (for adhering a chip) 50a and an opposite second surface (for adhering solder balls) 50b. A plurality of wire bonding pads 501 are disposed on the first surface 50a, and a plurality of second conductive pads 502 are disposed on the second surface 50b. The chip 51 has an active surface 51a with a plurality of electrode pads 511 thereon and an inactive surface 51b. The electrode pads 511 of the chip 51 electrically connect to the wire bonding pads 501 on the first surface 50a of the substrate 50 through a plurality of metal lines 54. The inactive surface 51b of the chip 51 is fixed on the first surface 50a of the substrate 50 by an adhesive material 52. In addition, the wire bond package structure 5 further comprises an encapsulant 55 to wrap the chip 51, the metal lines 54, and the wire bonding pads 501. The second conductive pads 502 on the second surface 50b of the package structure 5 electrically connect to the first conductive pads 301 on the first surface 30a of the package structure 3 by a plurality of solder balls 36.

Accordingly, the present invention can reduce the height of the package module to provide a more compact-sized and space-saving product. In addition, the efficiency for heat dissipating can be improved, resulting from the exposure of the chip. Furthermore, the present invention can resolve the alignment error caused by the shift of the chip in the process for wire bonding. The package structure with a chip embedded therein can further electrically connect to a flip chip package structure, a wire bond package structure, or another identical package structure so as to provide various products.

Although the present invention has been explained in relation to its preferred embodiment, it is to be understood that many other possible modifications and variations can be made without departing from the spirit and scope of the invention as hereinafter claimed.

What is claimed is:

1. A package structure with a chip embedded therein, comprising: a circuit board having a first surface, an opposite second surface, and a through cavity penetrating the circuit board, wherein the first surface of the circuit board has a plurality of first conductive pads and a plurality of wire bonding pads disposed thereon, and the second surface of the circuit board has a plurality of second conductive pads disposed thereon; and
a chip embedded in the through cavity of the circuit board, wherein the gap between the through cavity of the circuit board and the chip is filled with a filling material to fix the chip, the chip has an active surface with a plurality of electrode pads and an inactive surface, and the electrode pads electrically connect to the wire bonding pads of the circuit board by a plurality of metal lines.

2. The package structure as claimed in claim 1, wherein the circuit board is a two-layered or multi-layered circuit board.

3. The package structure as claimed in claim 1, wherein the material of the filling material is selected from the group consisting of organic dielectric material, liquid organic resin, and prepreg.

4. The package structure as claimed in claim 1, wherein the materials of the first conductive pads, the wire bonding pads and the second conductive pads are individually selected from the group consisting of copper, silver, gold, nickel/gold, nickel/palladium/gold, and the combination thereof.

5. The package structure as claimed in claim 1, wherein the material of the metal lines is gold.

6. The package structure as claimed in claim 1, further comprising an encapsulant to wrap the active surface of the chip, the metal lines, and the wire bonding pads of the circuit board.

7. The package structure as claimed in claim 6, wherein the material of the encapsulant is epoxy resin.

8. A stacked package module, comprising: a first package structure comprising a circuit board and a first chip, wherein the circuit board has a first surface, an opposite second surface, at least one through cavity penetrating the circuit board, a plurality of first conductive pads and a plurality of wire bonding pads disposed on the first surface, and a plurality of second conductive pads disposed on the second surface; the first chip is embedded in the through cavity of the circuit board; the gap between the through cavity of the circuit board and the first chip is filled with a filling material to fix the first chip; the first chip has an active surface with a plurality of electrode pads and an inactive surface; and the electrode pads electrically connect to the wire bonding pads of the circuit board by a plurality of metal lines; and
a second package structure comprising a second chip, wherein one surface of the second package structure has a plurality of second conductive pads, electrically connecting to the first conductive pads of the first package structure by a plurality of solder balls.

9. The stacked package module as claimed in claim 8, wherein the second package structure is the same as the first package structure.

10. The stacked package module as claimed in claim 8, wherein the second package structure is a flip chip package structure.

11. The stacked package module as claimed in claim 8, wherein the second package structure is a wire bond package structure.

12. The stacked package module as claimed in claim 8, further comprising an encapsulant to wrap the active surface of the first chip, the metal lines, and the wire bonding pads of the circuit board.

13. The stacked package module as claimed in claim 12, wherein the material of the encapsulant is epoxy resin.

14. The stacked package module as claimed in claim 8, wherein the circuit board is a two-layered or multi-layered circuit board.

15. The stacked package module as claimed in claim 8, wherein the material of the filling material is selected from the group consisting of organic dielectric material, liquid organic resin, and prepreg.

16. The stacked package module as claimed in claim 8, wherein the materials of the first conductive pads, the wire bonding pads and the second conductive pads are individually selected from the group consisting of copper, silver, gold, nickel/gold, nickel/palladium/gold, and the combination thereof.

17. The stacked package module as claimed in claim 8, wherein the material of the metal lines is gold.
